(19) United States
(12) Patent Application Publication
(10) Pub. No.: US 2009/0302418 A1
(43) Pub. Date: Dec. 10, 2009

(54) FUSE STRUCTURE OF A SEMICONDUCTOR DEVICE

(75) Inventors: Hyun-Soo CHUNG, Hwaseong-si (KR); Dong-Ho LEE, Seongnam-si (KR); Dong-Hyeon JANG, Suwon-si (KR); Eun-Chul AHN, Yongin-si (KR); Kun-Gu LEE, Seoul (KR); Chang-Woo SHIN, Gunpo-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD., Suwon-si (KR)

(21) Appl. No.: 12/478,365

(22) Filed: Jun. 4, 2009

(30) Foreign Application Priority Data
Jun. 10, 2008 (KR) 10-2008-0054120

(51) Int. Cl. H01L 23/525

(52) U.S. Cl. 257/529; 257/E23.149

(57) ABSTRACT

Provided is a fuse structure of a semiconductor device. The fuse structure may include an insulating layer pattern structure, a fuse and a protecting layer pattern. The insulating layer pattern structure may be formed on a substrate. The insulating layer pattern structure may have an opening. The fuse may be formed in the opening. The protecting layer pattern may be formed in the opening of the insulating layer pattern structure to cover the fuse.

### CROSS-REFERENCE TO RELATED APPLICATIONS

This application claims priority from Korean Patent Application No. 10-2008-0054120, filed Jun. 10, 2008, in the Korean Intellectual Property Office, the disclosure of which is incorporated herein by reference.

### SUMMARY

Exemplary embodiments of the present invention relate to a fuse structure of a semiconductor device and a method of forming the same. More particularly, exemplary embodiments of the present invention relate to a fuse structure of a semiconductor device that may be used for identifying an abnormal memory chip, and a method of forming the fuse structure.

Generally, a semiconductor device may be manufactured by a fabrication process, an electrical die sorting (EDS) process, an assembly process, a test process, etc.

The EDS process may include a pre-laser test process for testing semiconductor chips to identify abnormal semiconductor chips, a laser repair process for replacing the abnormal semiconductor chips with redundant normal semiconductor chips, a post-laser test process for testing the redundant normal semiconductor chips, etc.

The laser repair process may include a process for cutting a fuse, which may be connected to the abnormal semiconductor chip, using a laser, a process for replacing the abnormal semiconductor chip with the redundant normal semiconductor chip, etc.

Here, a region on which the laser repair process may be performed may be referred to as a fuse structure. A portion of a polysilicon layer or a metal wiring of the semiconductor chip may be used for the fuse of the fuse structure.

A fuse structure may include a fuse formed in an opening of an insulating interlayer, and an oxide layer configured to cover the fuse. The oxide layer may prevent moisture from infiltrating into the fuse by covering the fuse. Thus, the laser repair process may be performed on the fuse covered with the oxide layer that may have a sufficient thickness for exhibiting the above-mentioned function.

However, because the oxide layer may have a large thickness, failures may frequently occur in the repair process with respect to the fuse. That is, the fuse may not be completely cut by the laser due to the large thickness of the oxide layer.¹

Exemplary embodiments of the present invention provide a fuse structure of a semiconductor device that may be capable of preventing infiltration of moisture and may be adapted for a laser repair process.

Exemplary embodiments of the present invention also provide a method of forming the above-mentioned fuse structure.

According to an exemplary embodiment of the present invention, there is provided a fuse structure of a semiconductor device. The fuse structure may include an insulating layer pattern structure, a fuse and a protecting layer pattern. The insulating layer pattern structure may be formed on a substrate. The insulating layer pattern structure may have an opening. The fuse may be formed in the opening. The protecting layer pattern may be formed in the opening of the insulating layer pattern structure to cover the fuse.

In an exemplary embodiment, the insulating layer pattern structure may include a first insulating interlayer pattern and a second insulating interlayer pattern. The first insulating interlayer pattern may be formed on the substrate. The first insulating interlayer pattern may have a first opening configured to receive the fuse. The second insulating interlayer pattern may be formed on the first insulating interlayer pattern. The second insulating interlayer pattern may have a second opening in fluidic communication with the first opening and configured to receive the protecting layer pattern. Further, the fuse may be partially arranged on the second insulating interlayer pattern.

In an exemplary embodiment, the insulating layer pattern structure may further include a passivation layer. The passivation layer may be formed on the second insulating interlayer pattern. The passivation layer may have a third opening in fluidic communication with the second opening and configured to receive the protecting layer pattern. Further, the fuse may be partially arranged on the passivation layer.

In an exemplary embodiment, the insulating layer pattern structure may further include an insulating layer pattern. The insulating layer pattern may be formed on the passivation layer. The insulating layer pattern may have a fourth opening in fluidic communication with the third opening and configured to receive the protecting layer pattern. Further, the fuse may be partially arranged on the insulating layer pattern.

In an exemplary embodiment, the fuse may include a polysilicon layer, a metal layer, etc. The metal layer may have a structure where a titanium or titanium nitride layer and an aluminum layer may be sequentially stacked.

In an exemplary embodiment, the protecting layer pattern may include a vertical portion located in the opening, and a horizontal portion extending from an upper surface of the vertical portion along an upper surface of the insulating layer pattern structure. The protecting layer pattern may include a photosensitive polyimide layer.

According to an exemplary embodiment, there is provided a method of forming a fuse structure of a semiconductor device. In the method of forming the fuse structure of the semiconductor device, a first insulating interlayer pattern having a first opening may be formed on a substrate. A fuse may be formed in the first opening. A second insulating interlayer pattern may be formed on the first insulating interlayer pattern. The second insulating interlayer pattern may have a second opening configured to expose the fuse. A protecting layer pattern may be formed in the second opening to cover the fuse with the protecting layer pattern.

In an exemplary embodiment, the method may further include performing a laser repair process on the fuse before forming the protecting layer pattern.

In an exemplary embodiment, the method may further include forming a passivation layer on the second insulating interlayer pattern. The passivation layer may have a third opening in fluidic communication with the second opening. The method may further include forming an insulating layer pattern on the passivation layer. The insulating layer pattern may have a fourth opening in fluidic communication with the third opening.

In an exemplary embodiment, forming the fuse may include forming a polysilicon layer in the first opening. Alternatively, forming the fuse may include forming a titanium or titanium nitride layer in the first opening, and forming an aluminum layer on the titanium or titanium nitride layer.

In an exemplary embodiment, forming the protecting layer pattern may include forming a protecting layer on the second insulating interlayer pattern to fill up the second opening, and patterning the protecting layer.

According to an exemplary embodiment, the fuse may not be covered with the insulating layer. Thus, the laser repair process may be accurately performed on the fuse. Further, because the fuse may be covered with the protecting layer pattern after the laser repair process, moisture may be prevented from infiltrating into the fuse.

### BRIEF DESCRIPTION OF THE DRAWINGS

Exemplary embodiments will be more clearly understood from the following detailed description taken in conjunction with the accompanying drawings. FIGS. 1 to 12 represent non-limiting, exemplary embodiments as described herein.

FIG. 1 is a first cross-sectional view illustrating a fuse structure of a semiconductor device in accordance with a first exemplary embodiment;

FIGS. 2 to 9 are cross-sectional views illustrating a method of forming the fuse structure of the exemplary embodiment shown in FIG. 1;

FIG. 10 is a cross-sectional view illustrating a fuse structure of a semiconductor device in accordance with a second exemplary embodiment;

FIG. 11 is a cross-sectional view illustrating a fuse structure of a semiconductor device in accordance with a third exemplary embodiment; and

FIG. 12 is a cross-sectional view illustrating a fuse structure of a semiconductor device in accordance with a fourth exemplary embodiment.

### DETAILED DESCRIPTION OF EXEMPLARY EMBODIMENTS

Various exemplary embodiments will be described more fully hereinafter with reference to the accompanying drawings. The present invention may, however, be embodied in many different forms and should not be construed as limited to the exemplary embodiments set forth herein. Rather, these exemplary embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals in the drawings refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of exemplary embodiments (and intermediate structures). As such, variations from the shapes of the illustrated exemplary embodiments as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

### Exemplary Embodiment 1

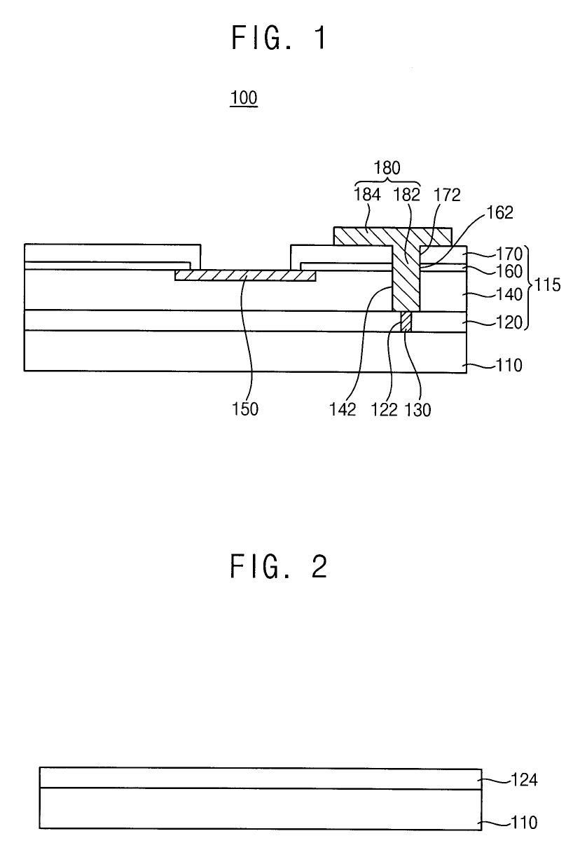

FIG. 1 is a first cross-sectional view illustrating a fuse structure of a semiconductor device in accordance with a first exemplary embodiment.

Referring to FIG. 1, the fuse structure 100 of this exemplary embodiment may include an insulating layer pattern structure 115, a fuse 130 and a protecting layer pattern 180.

The insulating layer pattern structure may be formed on a semiconductor substrate 110. Further, the insulating layer pattern structure may have an opening.

In this exemplary embodiment, the insulating layer pattern structure may include a first insulating interlayer pattern 120 and a second insulating interlayer pattern 140. The first insulating interlayer pattern 120 may be formed on the semiconductor substrate 110. The first insulating interlayer pattern 120 may have a first opening 122 configured to expose an upper surface of the semiconductor substrate 110. The second insulating interlayer pattern 140 may have a second opening 142 in fluidic communication with the first opening 122. The second opening 142 may have a width greater than that of the first opening 122. The first insulating interlayer pattern 120 and the second insulating interlayer pattern 140 may be made of insulating material that is substantially the same. Alternatively, the first insulating interlayer 120 and the second insulating interlayer 140 may be made of different insulating materials.

The fuse 130 may be formed in the first opening 122 of the first insulating interlayer pattern 120. Thus, an upper surface of the fuse 130 may be exposed through the second opening 142 of the second insulating interlayer pattern 140. In this exemplary embodiment, the fuse 130 may include a polysilicon layer in a semiconductor chip. That is, a portion of the polysilicon layer used for a wiring of the semiconductor chip may be used as the fuse 130. Further, the fuse 130 may have a thickness of about 1,500 Å.

A pad 150 of the semiconductor chip may be arranged on an upper surface of the second insulating interlayer pattern 140. A passivation layer 160 configured to expose the pad 150 may be formed on the second insulating layer pattern 140. The passivation layer 160 may have a third opening 162 in fluidic communication with the second opening 142. An insulating layer pattern 170 configured to expose the pad 150 may be formed on the passivation layer 160. The insulating layer pattern 170 may have a fourth opening 172 in fluidic communication with the third opening 162 of the passivation layer 160. Therefore, the fuse 130 may be exposed through the second opening 142, the third opening 162 and the fourth opening 172.

The protecting layer pattern 180 may be formed on the insulating layer pattern 170 to fill up the second opening 142, the third opening 162 and the fourth opening 172. Thus, the protecting layer pattern 180 may include a vertical portion 182 located in the second opening 142, the third opening 162 and the fourth opening 172, and a horizontal portion 184 extending from an upper surface of the vertical portion 182 along an upper surface of the insulating layer pattern 170. In this exemplary embodiment, the protecting layer pattern 180 may include polymer such as photosensitive polyimide. Because the protecting layer pattern 180 may cover the fuse 130, the protecting layer pattern may prevent moisture from infiltrating into the fuse 130.

In this exemplary embodiment, before forming the protecting layer pattern 180, a laser repair process may be performed on the fuse 130. Particularly, before forming the protecting layer pattern 180, the fuse 130, which may be connected with an abnormal semiconductor chip, may be cut using a laser. The abnormal semiconductor chip may then be replaced with a normal semiconductor chip. Because the fuse 130 may be exposed before forming the protecting layer pattern 180, the laser repair process may be accurately performed.

Further, the protecting layer pattern 180 may be used as a mask pattern in a process for patterning an insulating layer (not shown) to form the insulating layer pattern 170. Therefore, additional photo processes for forming the insulating layer pattern 170 may be omitted.

FIGS. 2 to 9 are cross-sectional views illustrating an exemplary embodiment of a method of forming the fuse structure in FIG. 1.

Referring to FIG. 2, a first insulating interlayer 124 may be formed on the semiconductor substrate 110.

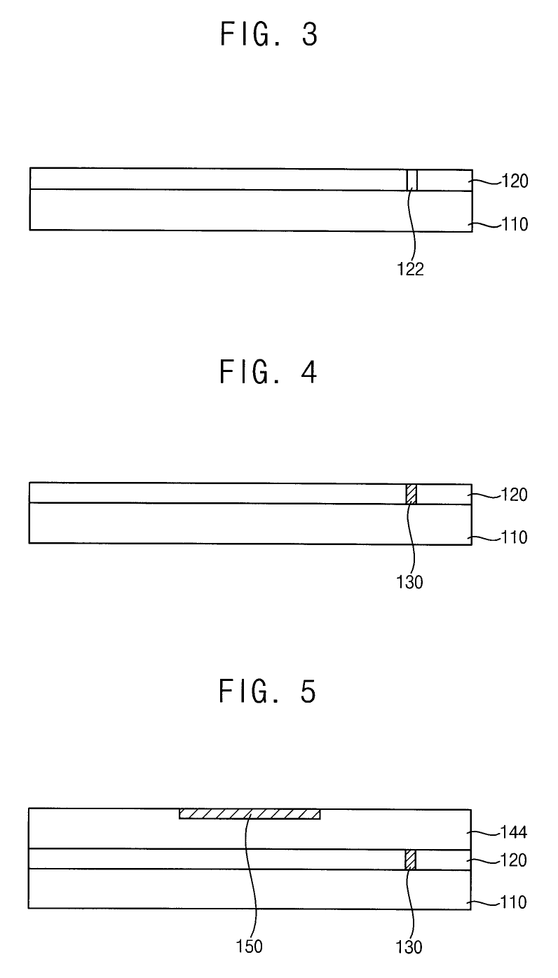

Referring to FIG. 3, a photoresist pattern (not shown) may be formed on the first insulating interlayer 124. The first insulating interlayer 124 may be etched using the photoresist pattern as an etch mask to form the first insulating interlayer pattern 120 having the first opening 122. The upper surface of the semiconductor substrate 110 may be exposed through the first opening 122. The photoresist pattern may then be removed by an ashing process and/or a stripping process.

Referring to FIG. 4, the fuse 130 may be formed in the first opening 122. In this exemplary embodiment, the fuse 130 may have an upper surface substantially coplanar with an upper surface of the first insulating interlayer pattern 120. The fuse 130 may correspond to a portion of a polysilicon layer in a semiconductor chip. The fuse 130 may have a thickness of about 1,500 Å. The fuse 130 may be electrically connected with the semiconductor chips.

Referring to FIG. 5, a second insulating interlayer 144 may be formed on the first insulating interlayer 120 and the fuse 130. Further, the pad 150, which may be electrically coupled to the semiconductor chip, may be formed on the second insulating interlayer 144. In this exemplary embodiment, the first insulating interlayer 124 and the second insulating interlayer 144 may be made of insulating material that is substantially the same. Alternatively, the first insulating interlayer 124 and the second insulating interlayer 144 may be made of different insulating materials.

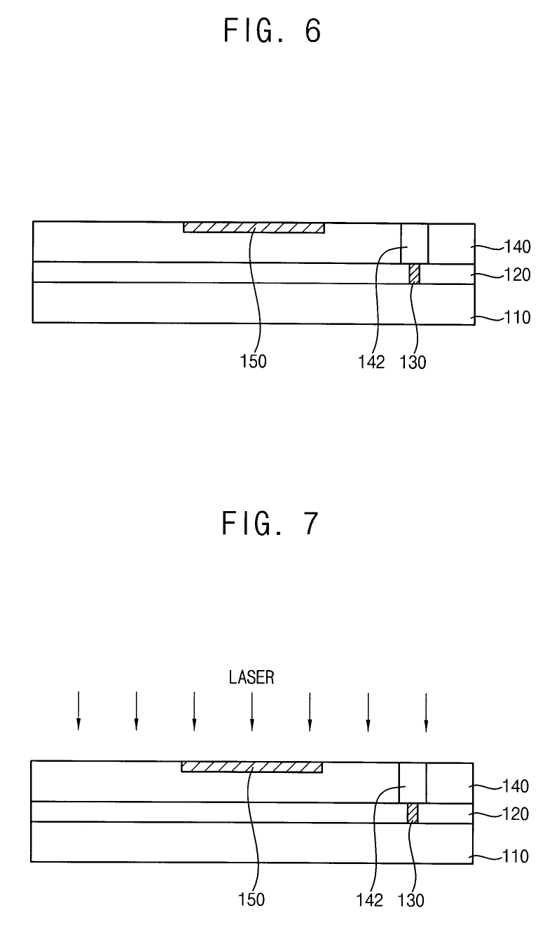

Referring to FIG. 6, a photoresist pattern (not shown) may be formed on the second insulating interlayer 144. The second insulating interlayer 144 may be etched using the photoresist pattern as an etch mask to form the second insulating interlayer pattern 140 having the second opening 142. The second opening 142 may be in fluidic communication with the first opening 122. The second opening 142 may have a width greater than that of the first opening 122. Thus, an entire upper surface of the fuse 130 may be exposed through the second opening 142. The photoresist pattern may then be removed by an ashing process and/or a stripping process.

Referring to FIG. 7, a laser repair process may be performed on the fuse 130. In this exemplary embodiment, a pre-laser test process for testing the semiconductor chips may be carried out. If an abnormal semiconductor chip is identified, a laser may be irradiated to the fuse 130 to cut the fuse 130. The abnormal semiconductor chip may then be replaced with a normal semiconductor chip. A post-laser test process may be performed on the normal semiconductor chip to test electrical characteristics of the normal semiconductor chip.

Here, the fuse 130 may be exposed through the second opening 142. Thus, the laser repair process for cutting the fuse 130 using the laser may be performed accurately and readily. As a result, a failure rate of the laser repair process may be reduced.

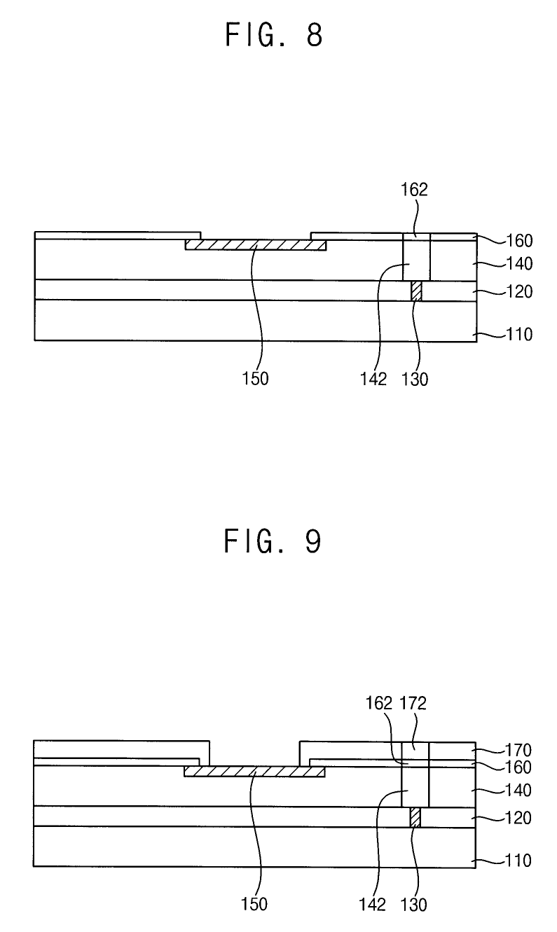

Referring to FIG. 8, the passivation layer 160 may be formed on the second insulating interlayer pattern 140. The passivation layer 160 may be configured to expose the pad 150. The passivation layer 160 may have a third opening 162 in fluidic communication with the second opening 142. Therefore, the fuse 130 may be exposed through the second opening 142 of the second insulating interlayer pattern 140 and the third opening 162 of the passivation layer 160.

Referring to FIG. 9, the insulating layer pattern 170 may be formed on the passivation layer 160. The insulating layer pattern 170 may be configured to expose the pad 150. The insulating layer pattern 170 may have a fourth opening 172 in fluidic communication with the third opening 162. Thus, the fuse 130 may be exposed through the second opening 142 of the second insulating interlayer pattern 140, the third opening 162 of the passivation layer 160, and the fourth opening 172 of the insulating layer pattern 170.

The protecting layer pattern 180 may be formed on the insulating layer pattern 170 to fill up the second opening 142 of the second insulating interlayer pattern 140, the third opening 162 of the passivation layer 160, and the fourth opening 172 of the insulating layer pattern 170, thereby completing the fuse structure 100 in FIG. 1. Here, the protecting layer pattern 180 may cover the fuse 130 so that moisture may not infiltrate into the fuse 130.

In this exemplary embodiment, a protecting layer (not shown) may be formed on the insulating layer pattern 170 to fill up the second opening 142 of the second insulating interlayer pattern 140, the third opening 162 of the passivation layer 160 and the fourth opening 172 of the insulating layer pattern 170. A photoresist pattern (not shown) may be formed on the protecting layer. The protecting layer may then be etched using the photoresist pattern as an etch mask to form the protecting layer pattern 180. Thus, the protecting layer pattern 180 may have the vertical portion 182 located in the second opening 142 of the second insulating interlayer pattern 140, the third opening 162 of the passivation layer 160 and the fourth opening 172 of the insulating layer pattern 170, and the horizontal portion 184 extending from an upper surface of the vertical portion 182 along an upper surface of the insulating layer pattern 170.

Here, the insulating layer pattern 170 may be formed using the protecting layer pattern 180. In this exemplary embodiment, an insulating layer (not shown) may be formed on the passivation layer 160. The fourth opening 172 may be formed through the insulating layer. The second opening 142 of the second insulating layer pattern 140, the third opening 162 of the passivation layer 160 and the fourth opening 172 of the insulating layer pattern 170 may be filled with the protecting layer pattern 180. The insulating layer may be etched using the protecting layer pattern 180 as an etch mask to form the insulating layer pattern 170 configured to expose the pad 150. That is, the protecting layer pattern 180 may be used as the etch mask without a process for forming an additional photoresist pattern as an etch mask.

According to this exemplary embodiment, the laser repair process may be performed on the fuse exposed through the opening. Thus, the fuse may be cut accurately and readily. Further, after performing the laser repair process, the fuse may be covered with the protecting layer pattern. As a result, moisture may not infiltrate into the fuse.

### Exemplary Embodiment 2

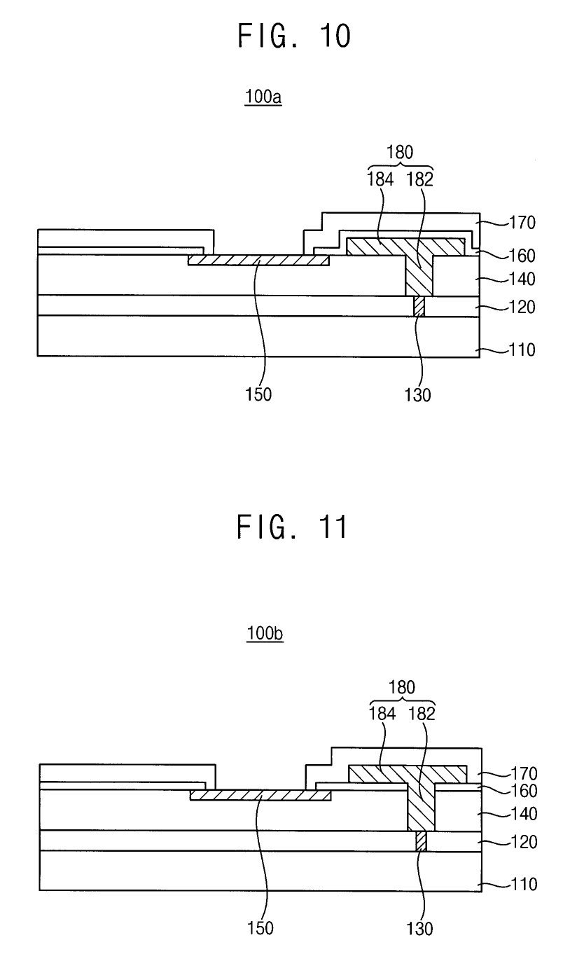

FIG. 10 is a cross-sectional view illustrating a fuse structure of a semiconductor device in accordance with a second exemplary embodiment.

The fuse structure 100a of this exemplary embodiment may include elements substantially the same as those of the fuse structure 100 in Exemplary Embodiment 1 except for a position of the protecting layer pattern 180. Thus, the same reference numerals refer to the same elements and any further illustrations with respect to the same elements are omitted herein for brevity.

Referring to FIG. 10, the protecting layer pattern 180 may be interposed between the second insulating layer pattern 140 and the passivation layer 160. Particularly, the horizontal portion 184 of the protecting layer pattern 180 may be interposed between the second insulating layer pattern 140 and the passivation layer 160.

In this exemplary embodiment, because the passivation layer 160 and the insulating layer pattern 170 may be sequentially stacked on the horizontal portion 184 of the protecting layer pattern 180, the passivation layer 160 and the insulating layer pattern 170 may not have the third opening 162 and the fourth opening 172, respectively.

A method of forming the fuse structure 100a in accordance with this example embodiment may be substantially the same as that illustrated in Exemplary Embodiment 1 except that the process for forming the protecting layer pattern 180 may be performed ahead of the process for forming the passivation layer 160, and the processes for forming the third opening 162 and the fourth opening 172 through the passivation layer 160 and the insulating layer pattern 170, respectively, may be omitted. Thus, any further illustrations with respect to the method of forming the fuse structure 100a are omitted herein for brevity.

### Exemplary Embodiment 3

FIG. 11 is a cross-sectional view illustrating a fuse structure of a semiconductor device in accordance with a third exemplary embodiment.

The fuse structure 100b of this exemplary embodiment may include elements substantially the same as those of the fuse structure 100 in Exemplary Embodiment 1 except for a position of the protecting layer pattern 180. Thus, the same reference numerals refer to the same elements and any further illustrations with respect to the same elements are omitted herein for brevity.

Referring to FIG. 11, the protecting layer pattern 180 may be interposed between the passivation layer 160 and the insulating layer pattern 170. Particularly, the horizontal portion 184 of the protecting layer pattern 180 may be interposed between the passivation layer 160 and the insulating layer pattern 170.

In this exemplary embodiment, because the insulating layer pattern 170 may be located on the horizontal portion 184 of the protecting layer pattern 180, the insulating layer pattern 170 may not have the fourth opening 172.

A method of forming the fuse structure 100b in accordance with this exemplary embodiment may be substantially the same as that illustrated in Exemplary Embodiment 1 except that the process for forming the protecting layer pattern 180 may be performed ahead of the process for forming the insulating layer pattern 170, and the process for forming the fourth opening 172 through the insulating layer pattern 170 may be omitted. Thus, any further illustrations with respect to the method of forming the fuse structure 100b are omitted herein for brevity.

### Exemplary Embodiment 4

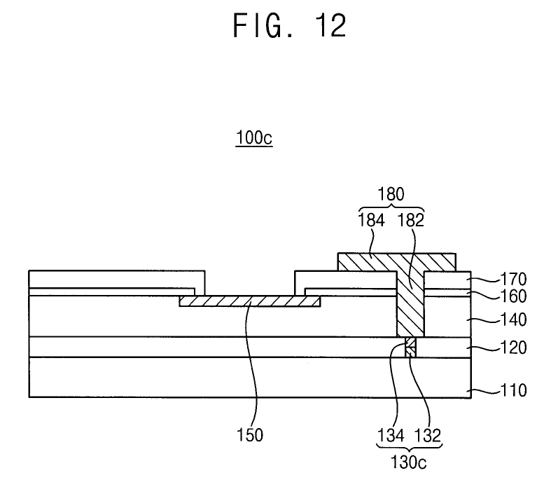

FIG. 12 is a cross-sectional view illustrating a fuse structure of a semiconductor device in accordance with a fourth exemplary embodiment.

The fuse structure 100c of this example embodiment may include elements substantially the same as those of the fuse structure 100 in Exemplary Embodiment 1 except for a fuse. Thus, the same reference numerals refer to the same elements and any further illustrations with respect to the same elements are omitted herein for brevity.

Referring to FIG. 12, the fuse 130c of this exemplary embodiment may include a metal layer. Particularly, the metal layer may include a structure where a titanium or titanium nitride layer 132 and an aluminum layer 134 may be sequentially stacked. In this exemplary embodiment, the titanium or titanium nitride layer 132 may have a thickness of about 150 Å. The aluminum layer 134 may have a thickness of about 2,000 Å.

In Exemplary Embodiment 4, the protecting layer pattern in Exemplary Embodiment 2 or 3 as well as Exemplary Embodiment 1 may be applied to the fuse structure 100c.

A method of forming the fuse structure 100c in accordance with this exemplary embodiment may be substantially the same as that illustrated in Exemplary Embodiment 1 except that a process for forming the fuse 130c may include a process for forming a double metal layer. Thus, any further illustrations with respect to the method of forming the fuse structure 100c are omitted herein for brevity.

According to an exemplary embodiment, the fuse 130c may not be covered with the insulating layer. Thus, the laser repair process may be accurately performed on the exposed fuse 130c. Further, after performing the laser repair process, the fuse 130c may be covered with the protecting layer pattern. Therefore, moisture may not infiltrate into the fuse 130c.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the spirit of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

1. A fuse structure of a semiconductor device comprising:
an insulating layer pattern structure disposed on a substrate, the insulating layer pattern structure having an opening;
a fuse disposed in the opening; and
a protecting layer pattern disposed in the opening of the insulating layer pattern structure such that the protecting layer pattern covers the fuse.

2. The fuse structure of claim 1, wherein the insulating layer pattern structure comprises:
a first insulating interlayer pattern disposed on the substrate; and
a second insulating interlayer pattern disposed on the first insulating interlayer pattern;
wherein the opening in the insulating layer pattern structure comprises a first opening in the first insulating interlayer pattern in which the fuse is disposed, and a second opening in the second insulating interlayer pattern that is in fluidic communication with the first opening and in which the protecting layer pattern is disposed.

3. The fuse structure of claim 2, wherein the fuse is partially arranged on the second insulating interlayer pattern.

4. The fuse structure of claim 2, wherein the insulating layer pattern structure further comprises a passivation layer disposed on the second insulating interlayer pattern; and
wherein the opening in the insulating layer pattern structure further comprises a third opening in the passivation layer that is in fluidic communication with the second opening in which the protecting layer pattern is disposed.

5. The fuse structure of claim 4, wherein the fuse is partially arranged on the passivation layer.

6. The fuse structure of claim 4, wherein the insulating layer pattern structure further comprises an insulating layer pattern disposed on the passivation layer; and
wherein the opening in the insulating layer pattern structure further comprises a fourth opening in the insulating layer pattern that is in fluidic communication with the third opening and in which the protecting layer pattern is disposed.

7. The fuse structure of claim 6, wherein the fuse is partially arranged on the insulating layer pattern.

8. The fuse structure of claim 1, wherein the fuse comprises a polysilicon layer.

9. The fuse structure of claim 1, wherein the fuse comprises a metal layer.

10. The fuse structure of claim 9, wherein the metal layer comprises a titanium or titanium nitride layer sequentially stacked with an aluminum layer.

11. The fuse structure of claim 1, wherein the protecting layer pattern comprises:
a vertical portion located in the opening; and
a horizontal portion adjacent to an upper surface of the vertical portion and extending along an upper surface of the insulating layer pattern structure.

12. The fuse structure of claim 1, wherein the protecting layer pattern comprises a photosensitive polyimide layer.

13-20. (canceled)
